(19) United States
(12) Patent Application Publication
(10) Pub. No.: US 2009/0127661 A1
(43) Pub. Date: May 21, 2009

(54) NITRIDE SEMICONDUCTOR DEVICE AND METHOD OF MANUFACTURING THE SAME

(75) Inventors: Katsuomi Shiozawa, Tokyo (JP); Kyozo Kanamoto, Tokyo (JP); Toshiyuki Oishi, Tokyo (JP); Hiroshi Kurokawa, Tokyo (JP); Kazushige Kawasaki, Tokyo (JP); Shinji Abe, Tokyo (JP); Hitoshi Sakuma, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: MITSUBISHI ELECTRIC CORPORATION, Tokyo (JP)

(21) Appl. No.: 12/271,946

(22) Filed: Nov. 17, 2008

(30) Foreign Application Priority Data
Nov. 20, 2007 (JP) 2007-300004

(51) Int. Cl. H01L 29/20; H01L 21/31

(52) U.S. Cl. 257/613; 438/787; 257/E29.089; 257/E21.24

(57) ABSTRACT

Semiconductor devices, in particular nitride semiconductor devices for use in the manufacture of laser diodes, prevent peeling-off of the electrode, and at the same time reduces the complexity of processes and a reduction in yield. A nitride semiconductor device according to the invention includes a P-type nitride semiconductor layer with a ridge on its surface, an SiO₂ film covering at least the side face of the ridge, an adherence layer formed on a surface of the SiO₂ film and composed mainly of silicon, and a P-type electrode formed on the upper surface of the ridge and on a surface of the adherence layer.

### BACKGROUND OF THE INVENTION

1. Field of the Invention

The present invention relates to nitride semiconductor devices and methods of manufacturing the same.

2. Description of the Background Art

Conventional semiconductor devices, in particular nitride semiconductor devices for use in the manufacture of laser diodes, in many cases adopt what is called a “ridge structure” in which an electrode is formed via an insulation film formed on a ridge side wall. However, insufficient adhesion between the insulation film and an electrode material can possibly cause peeling-off of the electrode from the insulation film, and consequently, peeling-off of the electrode from a semiconductor layer. This peeling-off of the electrode can further cause an increase in the operating voltage for driving the laser diodes or variations in the properties due to heat generation during operation, thus accompanying a problem of difficulty in providing stable operation output within a specified temperature range.

In view of the above problems, for example, Japanese Patent Application Laid-open No. 2005-51137 discloses a technique for obtaining good electrode adhesion by forming an adherence layer of a heat-treated platinum metal between an electrode and an insulation film on the ridge side wall. Furthermore, Japanese Patent Application Laid-open No. 2007-134445 discloses a technique for forming a protection film of zirconium oxide or the like, which has a density or surface roughness that meets certain requirements, between the ridge side wall and an electrode.

The technique disclosed in Japanese Patent Application Laid-open No. 2005-51137, however, has a drawback that a great difference in material between the insulation film and the adherence layer can complicate device manufacturing processes or can have an adverse effect on the optical properties of a device, which may lead to a reduction in yield. The technique disclosed in Japanese Patent Application Laid-open No. 2007-134445 also has the drawback of increased complexity of device manufacturing processes.

### SUMMARY OF THE INVENTION

It is an object of the invention to provide a nitride semiconductor device that prevents peeling-off of the electrode, and at the same time reduces the complexity of processes and a reduction in yield.

According to an aspect of the invention, the nitride semiconductor device includes a P-type semiconductor layer, an insulation film, an adherence layer, and an electrode. The P-type semiconductor layer has a ridge on its surface. The insulation film covers at least a side face of the ridge. The adherence layer is formed on a surface of the insulation film and composed mainly of silicon. The electrode is formed on an upper surface of the ridge and on a surface of the adherence layer.

According to another aspect of the invention, the nitride semiconductor device includes a P-type semiconductor layer, an insulation film, an adherence layer, and an electrode. The P-type semiconductor layer has a ridge on its surface. The insulation film covers at least a side face of the ridge. The adherence layer is formed on a surface of the insulation film and composed mainly of Ti or Al. The electrode is formed on an upper surface of the ridge and on a surface of the adherence layer.

According to still another aspect of the invention, the nitride semiconductor device includes a P-type semiconductor layer, an insulation film, and an electrode. The P-type semiconductor layer has a ridge on its surface. The insulation film is formed of a silicon oxide film which covers at least a side face of the ridge, and the silicon composition of which is nonuniform along the film thickness. The electrode is formed on an upper surface of the ridge and on a surface of the insulation film.

The invention is also directed to a method of manufacturing a nitride semiconductor device. The nitride semiconductor device includes a P-type semiconductor layer, an insulation film, and an electrode. The P-type semiconductor layer has a ridge on its surface. The insulation film is formed of a silicon oxide film which covers at least a side face of the ridge, and the silicon composition of which is nonuniform along the film thickness. The electrode is formed on an upper surface of the ridge and on a surface of the insulation film. The silicon composition of the insulation film increases toward the surface of the insulation film. The method includes the step of forming the insulation film by sputtering silicon so that a mixture ratio of oxygen gas to argon gas is changed such that the oxygen gas content is reduced from a high level to a low level.

The formation of the adherence layer on the surface of the insulation film on the side face of the ridge can prevent peeling-off of the electrode, thus stabilizing the formation of a low-resistance electrode, and can reduce the operating voltage of a semiconductor device such as a laser diode. This allows a reduction of heat generation during operation, thereby providing high-power and stable operation. Besides, composing the adherence layer mainly of silicon can avoid the problem that the insulation film and the adherence layer have a great difference in material. This prevents peeling-off of the electrode on the ridge while preserving the properties without any great change in the manufacturing processes and in the device configuration, thus reducing the complexity of processes and a reduction in yield.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross-sectional view of a nitride semiconductor device according to a first preferred embodiment of the invention;

FIG. 2 is a cross-sectional view of a light-emitting nitride semiconductor device according to the first preferred embodiment of the invention;

FIGS. 3 to 6 are cross-sectional views illustrating a method of manufacturing a nitride semiconductor device according to the first preferred embodiment of the invention;

FIG. 7 is a cross-sectional view of a nitride semiconductor device according to a second preferred embodiment of the invention; and

FIG. 8 is a graph showing the silicon composition of a SiO₂ film according to the second preferred embodiment of the invention.

### DESCRIPTION OF THE PREFERRED EMBODIMENTS

Referring now to the drawings, preferred embodiments of the invention is described in detail.

### First Preferred Embodiment

### (Configuration)

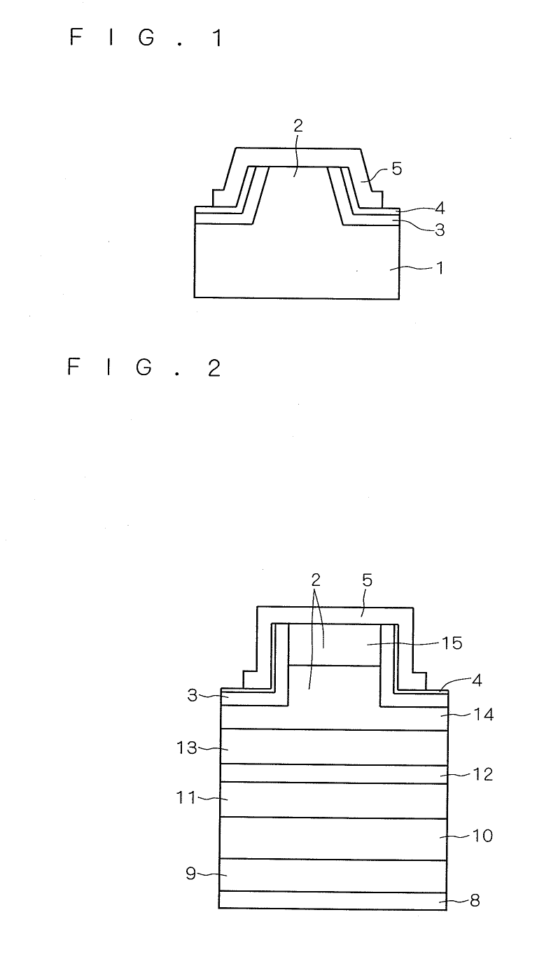

FIG. 1 is a cross-sectional view illustrating the essential parts of a nitride semiconductor device according to the present preferred embodiment. A P-type nitride semiconductor layer (P-type semiconductor layer) 1 of a P-type nitride semiconductor has a ridge 2 formed on its upper surface, and a SiO₂ film (insulation film) 3 and a Si adherence layer (adherence layer) 4 of silicon are successively formed to cover the side face of the ridge 2 and the upper surface of the P-type nitride semiconductor layer 1 joined to the bottom edge of the ridge side face. Furthermore, a P-type electrode (electrode) 5 is formed to cover the upper surface of the ridge 2 and the surface of the Si adherence layer 4 on the side face of the ridge 2.

FIG. 2 is a cross-sectional view of a light-emitting nitride semiconductor device, showing an example of the entire nitride semiconductor device in FIG. 1. An n electrode 8, an n-GaN substrate 9, an n-AlGaN cladding layer 10, an n-GaN guide layer 11, an active layer 12, a P—GaN guide layer 13, a P—AlGaN cladding layer 14, and a P—GaN contact layer 15 are laminated in layers in order from bottom to top. The ridge 2 is formed in the P—AlGaN cladding layer 14 and the P—GaN contact layer 15, and the SiO₂ film 3 and the Si adherence layer 4 are successively formed on the side face of the ridge 2 and on the upper surface of the P—AlGaN cladding layer 14 joined to the bottom edge of the ridge side face. Furthermore, the P-type electrode 5 is formed to cover the upper surface of the ridge 2 and the surface of the Si adherence layer 4 on the side face of the ridge 2.

### (Manufacturing Method)

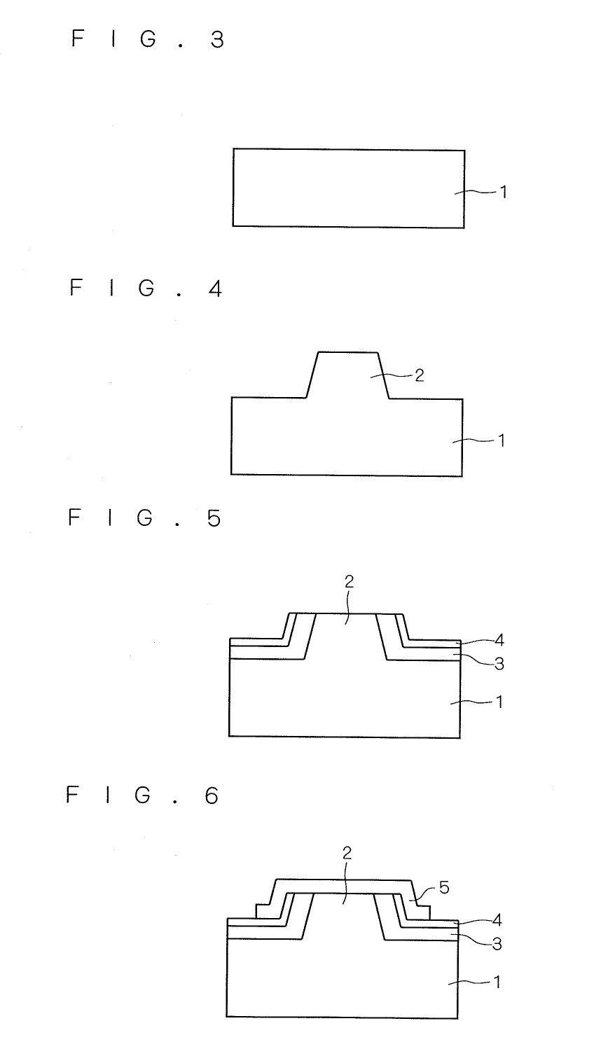

Next is described a method of manufacturing the essential parts of the nitride semiconductor device according to the present preferred embodiment. FIGS. 3 to 6 are cross-sectional views illustrating this manufacturing method.

First, a resist pattern (not shown) is formed by transferring on the surface of the P-type nitride semiconductor layer 1 in FIG. 3, and using this resist pattern as a mask, the P-type nitride semiconductor device I is etched to form the ridge 2 as shown in FIG. 4. The etching applied here for the formation of the ridge 2 is dry etching. The dry etching may use techniques such as ICP (high-frequency inductively coupled plasma), RIE (reactive ion etching), or ECR (electron cyclotron resonance). The etching gas used in this example is a chlorine (Cl) gas. The etching depth will vary depending on the device properties, but it must be on the order of 0.5 μm. Instead of a resist mask, other materials such as an insulation film may be used for the etching of the ridge 2, even in which case similar ridge machining can be achieved.

After the formation of the ridge 2, as shown in FIG. 5, the SiO₂ film 3 and the Si adherence layer 4 are successively formed in order of mention on the side face of the ridge 2 and on the upper surface of the P-type semiconductor layer 1 joined to the bottom edge of the ridge side face.

Examples of the processes for forming the SiO₂ film 3 include evaporation, sputtering, and CVD (chemical vapor deposition). The thickness of the SiO₂ film 3 is determined according to the optical properties of the device, but it must be on the order of, for example, 200 nm. Although SiO₂ (silicon oxide) is desirable from the viewpoint of device manufacture, any other insulation film such as Si₃N₄ (silicon nitride) or SiON (silicon oxynitride) may be used as long as it can meet optical property requirements.

Similarly, the Si adherence layer 4 can also be formed on this SiO2 film 3 by evaporation, sputtering, CVD, or the like. The use of the same technique as used for the SiO₂ film 3 will allow successive formation of the SiO2 film 3 and the Si adherence layer 4 by one operation, and on the other hand, the use of different techniques is also possible. The Si adherence layer 4 should desirably have such a thickness that can improve adhesion without exerting any effect on the device properties. For example, it may preferably be 50 nm or less, and more preferably 25 nm or less. The thickness of 25 nm or less will not affect not only the device properties, but also the processes in device manufacture.

Since the Si adherence layer 4 is used for improving the adhesion of the SiO₂ film 3 to the P-type electrode 5, the thickness of the Si adherence layer 4 may be uniform, or may be nonuniform within a range that can provide good adhesion. The Si adherence layer 4 may be of single crystalline silicon or amorphous silicon. If the processes permit, similar effects can also be attained by forming a metal such as Ti or Al, instead of silicon. The SiO₂ film 3 and the Si adherence layer 4 formed in this way are then selectively removed by a lift-off or etch-back process so as to be formed on the side face of the ridge 2 and on the upper surface of the P-type semiconductor layer 1 joined to the bottom edge of the ridge side face.

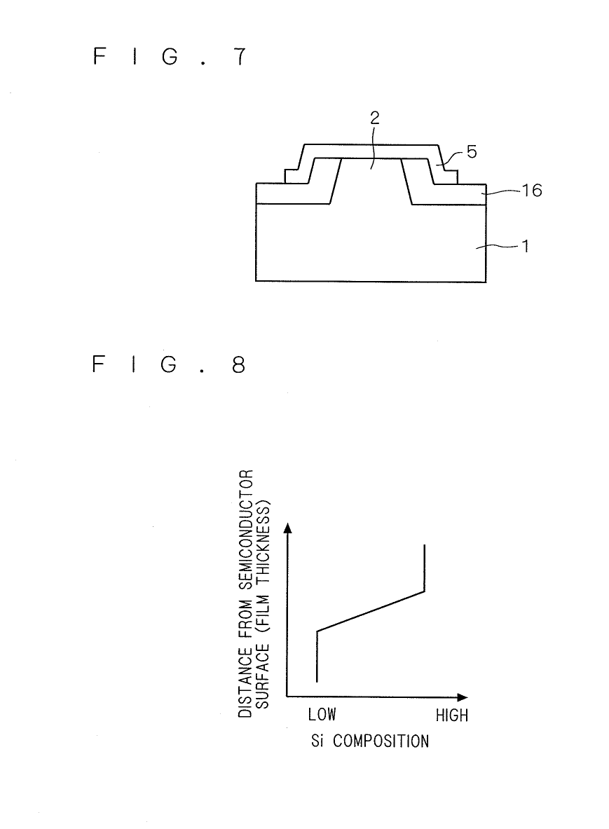

After the formation of the SiO₂ film 3 and the Si adherence layer 4, as shown in FIG. 6, the P-type electrode 5 is formed to cover the upper surface of the ridge 2 and the surface of the Si adherence layer 4 on the side face of the ridge 2.

Referring to the formation of the P-type electrode 5, an electrode material is first deposited using a technique, such as evaporation or sputtering, and then selectively formed by a lift-off process on the top of the ridge 2 and on the surface of the Si adherence layer 4 on the side face of the ridge 2. The P-type electrode 5 may be made of any material that can establish an ohmic contact with the P-type nitride semiconductor layer 1; for example, it is preferably made of a material containing palladium (Pd), and more preferably, a material containing palladium (Pd) and tantalum (Ta). Furthermore, applying an organic coating material containing silicon as pretreatment prior to the formation of a P-type electrode material can also lead to an improvement in adhesion. For example, the use of a material such as hexamethyldisilazane (HMDS) allows selective formation of the P-type electrode 5 on the SiO₂ film 3, thus further improving adhesion without deteriorating the properties of the P-type electrode 5. In addition, performing heat treatment in an atmosphere containing oxygen after the formation of the P-type electrode 5 can provide an ohmic contact.

### (Advantageous Effects)

According to the invention, the formation of the P-type electrode 5 via the Si adherence layer 4 on the SiO₂ film 3 on the side face of the ridge 2 can prevent peeling-off of the electrode, thus stabilizing the formation of the low-resistance electrode, and can reduce the operating voltage of the semiconductor device. This allows a reduction of heat generation during operation, thus providing high-power and stable operation. It is also possible to avoid the problem that the insulation film and the adherence layer has a great difference in material. This preventing peeling-off of the electrode on the ridge 2 while preserving the properties without any great change in the manufacturing processes and in the device configuration, thus reducing the complexity of processes and a reduction in yield.

### Second Preferred Embodiment

### (Configuration)

FIG. 7 is a cross-sectional view illustrating the essential parts of a nitride semiconductor device according to the present preferred embodiment. The P-type nitride semiconductor layer 1 of a P-type nitride semiconductor has the ridge 2 formed on its upper surface, and an SiO₂ film 16 is formed on the side face of the ridge 2 and on the upper surface of the P-type nitride semiconductor layer 1 joined to the bottom edge of the ridge side face. Furthermore, the P-type electrode 5 is formed to cover the upper surface of the ridge 2 and the surface of the SiO₂ film 16 on the side face of the ridge 2.

In the example shown, the silicon composition of the SiO₂ film 16 is controlled so as to be nonuniform along the film thickness. FIG. 8 shows the composition of the SiO₂ film 16. The silicon composition of the SiO₂ film 16 is made to increase toward the surface of the SiO₂ film 16.

### (Manufacturing Method)

Next is described a method of manufacturing the nitride semiconductor device in FIG. 7. In the semiconductor device with the ridge 2, the SiO₂ film 16 is formed on the side face of the ridge 2 and on the upper surface of the P-type nitride semiconductor layer 1 joined to the bottom edge of the ridge side face, and the P-type electrode 5 is formed to cover the upper surface of the ridge 2 and the surface of the SiO₂ film 16 on the side face of the ridge 2.

Referring to the formation of the SiO2 film 16, for example silicon is subjected to sputtering so that a mixture ratio of oxygen gas to argon gas is changed such that the oxygen gas content is reduced from a high level to a low level. This changes the concentration of oxygen within the film, allowing the control of the composition of the film deposited. Other features, such as the formation of the ridge 2 and the P-type electrode 5, are the same as those described in the first preferred embodiment 1, so the detailed description thereof is omitted herein.

### (Advantageous Effects)

According to the invention, making the silicon composition of the SiO2 film 16 to increase toward the surface of the SiO2 film 16 can prevent peeling-off of the electrode, thus stabilizing the formation of the low-resistance electrode, and can reduce the operating voltage of the semiconductor device. This allows a reduction of heat generation during operation, thus providing high-power and stable operation.

While the invention has been shown and described in detail, the foregoing description is in all aspects illustrative and not restrictive. It is therefore understood that numerous modifications and variations can be devised without departing from the scope of the invention.

What is claimed is:

1. A nitride semiconductor device comprising:
a P-type semiconductor layer having a ridge on its surface;
an insulation film covering at least a side face of said ridge;
an adherence layer formed on a surface of said insulation film and composed mainly of silicon; and
an electrode formed on an upper surface of said ridge and on a surface of said adherence layer.

2. The nitride semiconductor device according to claim 1, wherein
said adherence layer is composed mainly of single crystalline silicon or amorphous silicon.

3. The nitride semiconductor device according to claim 1, wherein
said adherence layer is mainly made of an organic material containing silicon.

4. The nitride semiconductor device according to claim 3, wherein
said organic material is composed mainly of hexamethyldisilazane.

5. The nitride semiconductor device according to claim 1, wherein
said adherence layer has a thickness of 50 nm or less.

6. The nitride semiconductor device according to claim 1, wherein
said insulation film is composed mainly of silicon oxide, silicon nitride, or silicon oxynitride.

7. The nitride semiconductor device according to claim 1, wherein
said electrode is composed at least mainly of palladium (Pd).

8. The nitride semiconductor device according to claim 1, wherein
said electrode is composed at least mainly of palladium (Pd) and tantalum (Ta).

9. A nitride semiconductor device comprising:
a P-type semiconductor layer having a ridge on its surface;
an insulation film covering at least a side face of said ridge;
an adherence layer formed on a surface of said insulation film and composed mainly of Ti or Al; and
an electrode formed on an upper surface of said ridge and on a surface of said adherence layer.

10. The nitride semiconductor device according to claim 9, wherein
said adherence layer has a thickness of 50 nm or less.

11. The nitride semiconductor device according to claim 9, wherein
said insulation film is composed mainly of silicon oxide, silicon nitride, or silicon oxynitride.

12. The nitride semiconductor device according to claim 9, wherein
said electrode is composed at least mainly of palladium (Pd).

13. The nitride semiconductor device according to claim 9, wherein
said electrode is composed at least mainly of palladium (Pd) and tantalum (Ta).

14. A nitride semiconductor device comprising:
a P-type semiconductor layer having a ridge on its surface;
an insulation film formed of a silicon oxide film which covers at least a side face of said ridge, and the silicon composition of which is nonuniform along the film thickness; and
an electrode formed on an upper surface of said ridge and on a surface of said insulation film.

15. The nitride semiconductor device according to claim 14, wherein
the silicon composition of said insulation film increases toward the surface of said insulation film.

16. A method of manufacturing a nitride semiconductor device,
said nitride semiconductor device comprising:
a P-type semiconductor layer having a ridge on its surface;
an insulation film formed of a silicon oxide film which cover at least a side face of said ridge, and the silicon composition of which is nonuniform along the film thickness; and
an electrode formed on an upper surface of said ridge and on a surface of said insulation film,
the silicon composition of said insulation film increasing toward the surface of said insulation film,
said method comprising the step of forming said insulation film by sputtering silicon so that a mixture ratio of oxygen gas to argon gas is changed such that the oxygen gas content is reduced from a high level to a low level.

17. The nitride semiconductor device according to claim 14, wherein
said electrode is composed at least mainly of palladium (Pd).

18. The nitride semiconductor device according to claim 14, wherein
said electrode is composed at least mainly of palladium (Pd) and tantalum (Ta).
